(19) United States
(12) Patent Application Publication
(10) Pub. No.: US 2024/0128190 A1
(43) Pub. Date: Apr. 18, 2024

(54) SEMICONDUCTOR PACKAGE AND METHOD OF MANUFACTURING THE SAME

(71) Applicant: SAMSUNG ELECTRONICS CO., LTD., SUWON-SI (KR)

(72) Inventors: Seunghwan Kim, Suwon-si (KR); Yongkwan Lee, Suwon-si (KR); Gyuhyeong Kim, Suwon-si (KR); Jungjoo Kim, Suwon-si (KR); Jongwan Kim, Suwon-si (KR); Junwoo Park, Suwon-si (KR); Taejun Jeon, Suwon-si (KR); Junhyeung Jo, Suwon-si (KR)

(21) Appl. No.: 18/486,546

(22) Filed: Oct. 13, 2023

(30) Foreign Application Priority Data
Oct. 14, 2022 (KR) 10-2022-0132479
May 12, 2023 (KR) 10-2023-0061533

(51) Int. Cl. H01L 23/528; H01L 21/48; H01L 21/56; H01L 23/00; H01L 23/31

(52) U.S. Cl. CPC H01L 23/5283; H01L 21/485; H01L 21/56; H01L 23/3157; H01L 24/05; H01L 24/13; H01L 2224/05008; H01L 2224/13026

(57) ABSTRACT

A semiconductor package includes a lower substrate including a lower interconnection layer; an upper substrate on the lower substrate, a recessed surface having a step difference, and an upper interconnection layer having a through-hole extending from the recessed surface to the first surface of the upper substrate and electrically connected to the lower interconnection layer; semiconductor chip between the recessed surface of the upper substrate and the lower substrate and including connection pads electrically connected to the lower interconnection layer; interconnect structure between the second surface of the upper substrate and the lower substrate and electrically connecting the lower interconnection layer to the upper interconnection layer; and an insulating member including a first portion covering at least a portion of the semiconductor chip and interconnect structure, a second portion extending from the first portion into the through-hole, and a third portion covering at least a portion of the first surface.

### CROSS-REFERENCE TO RELATED APPLICATION(S)

This application claims benefit of priority to Korean Patent Application No. 10-2023-0061533 filed on May 12, 2023 and Korean Patent Application No. 10-2022-0132479 filed on Oct. 14, 2022 in the Korean Intellectual Property Office, the disclosures of which are incorporated herein by reference in their entirety.

### BACKGROUND

The present disclosure relates to a semiconductor package and a method of manufacturing the same.

In response to the trend for miniaturization and high performance of electronic devices, a package-on-package (PoP) technique using an interposer substrate has been developed. As the thickness of a semiconductor package to which an interposer substrate is coupled has been reduced, quality assurance issues due to flux residues and formation of voids in an encapsulating process have emerged along with various structural limitations.

### SUMMARY

An example embodiment of the present disclosure is to provide a semiconductor package, which may remove flux residues generated in a process of connecting an upper substrate to a lower substrate, and may reduce voids generated in a process of filling an encapsulant.

According to an example embodiment of the present disclosure, a semiconductor package includes a lower substrate including a lower interconnection layer; an upper substrate on the lower substrate, including a first surface and a second surface opposite to each other, a recessed surface having a step difference from the second surface, a through-hole extending from the recessed surface to the first surface and an upper interconnection layer electrically connected to the lower interconnection layer; a semiconductor chip disposed between the recessed surface of the upper substrate and the lower substrate and including connection pads electrically connected to the lower interconnection layer; an interconnect structure disposed between the second surface of the upper substrate and the lower substrate and electrically connecting the lower interconnection layer to the upper interconnection layer; and an insulating member including a first portion covering at least a portion of each of the semiconductor chip and the interconnect structure between the upper substrate and the lower substrate, a second portion extending from the first portion into the through-hole, and a third portion extending from the second portion and covering at least a portion of the first surface of the upper substrate.

According to an example embodiment of the present disclosure, a semiconductor package includes a lower substrate including a lower interconnection layer; a semiconductor chip disposed on the lower substrate and electrically connected to the lower interconnection layer; an upper substrate disposed on the semiconductor chip and including interconnection pads surrounding a region overlapping the semiconductor chip, and at least one through-hole spaced apart from the interconnection pads; at least one mold line disposed on the upper substrate and spaced apart from the interconnection pads and extending in a first direction from the through-hole; an encapsulant configured to encapsulate at least a portion of the semiconductor chip between the upper substrate and the lower substrate and connected to the mold line through the through-hole.

According to an example embodiment of the present disclosure, a method of manufacturing a semiconductor package includes disposing a semiconductor chip on a preliminary lower substrate; preparing a preliminary upper substrate having a recessed surface and a through-hole extending from the recessed surface, wherein the recessed surface has a step difference from a lower surface of the preliminary upper substrate; forming interconnect structures between the preliminary lower substrate and the preliminary upper substrate; introducing a flux cleaning liquid between the preliminary lower substrate and the preliminary upper substrate and through the through-hole; and forming an encapsulating layer encapsulating at least a portion of each of the semiconductor chip and the interconnect structures and a preliminary mold line connected to the encapsulating layer through the through-hole by filling an insulating material between the preliminary lower substrate and the preliminary upper substrate that extends through the through-hole.

### BRIEF DESCRIPTION OF DRAWINGS

The above and other aspects, features, and advantages in the example embodiment will be more clearly understood from the following detailed description, taken in combination with the accompanying drawings, in which:

FIG. 1A is a diagram illustrating an upper surface of an upper substrate of a semiconductor package, according to an embodiment of the present disclosure;

FIG. 1B is a cross-sectional diagram illustrating a semiconductor package illustrated in FIG. 1A taken along line X-X′;

FIG. 1C is a cross-sectional diagram illustrating a semiconductor package illustrated in FIG. 1A taken along line Y-Y′;

FIGS. 2A to 2G are diagrams and cross-sectional diagrams illustrating processes of a method of manufacturing a semiconductor package, according to an embodiment of the present disclosure;

FIG. 3 is a diagram illustrating an upper surface of an upper substrate of a semiconductor package, according to an embodiment of the present disclosure;

FIG. 4 is a diagram illustrating an upper surface of an upper substrate of a semiconductor package, according to an embodiment of the present disclosure;

FIG. 5A is a diagram illustrating an upper surface of an upper substrate of a semiconductor package, according to an embodiment of the present disclosure;

FIG. 5B is a cross-sectional diagram illustrating the semiconductor package illustrated in FIG. 5A taken along line C-C′;

FIG. 6A is a diagram illustrating an upper surface of an upper substrate of a semiconductor package, according to an embodiment of the present disclosure;

FIG. 6B is a cross-sectional diagram illustrating the semiconductor package illustrated in FIG. 6A taken along line D-D′;

FIG. 7A is a diagram illustrating an upper surface of an upper substrate of a semiconductor package, according to an embodiment of the present disclosure;

FIG. 7B is a cross-sectional diagram illustrating the semiconductor package illustrated in FIG. 7A taken along line E-E′; and

FIG. 8 is a cross-sectional diagram illustrating a semiconductor package, according to an embodiment of the present disclosure.

### DETAILED DESCRIPTION

Hereinafter, embodiments in the embodiment will be described as follows with reference to the accompanying drawings.

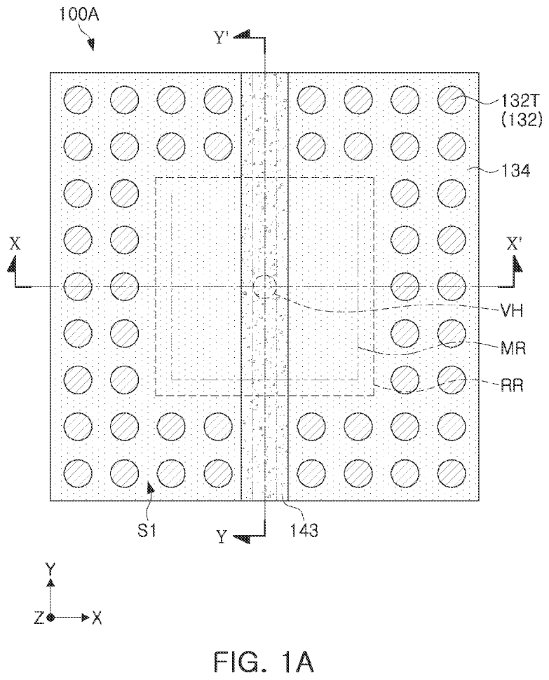

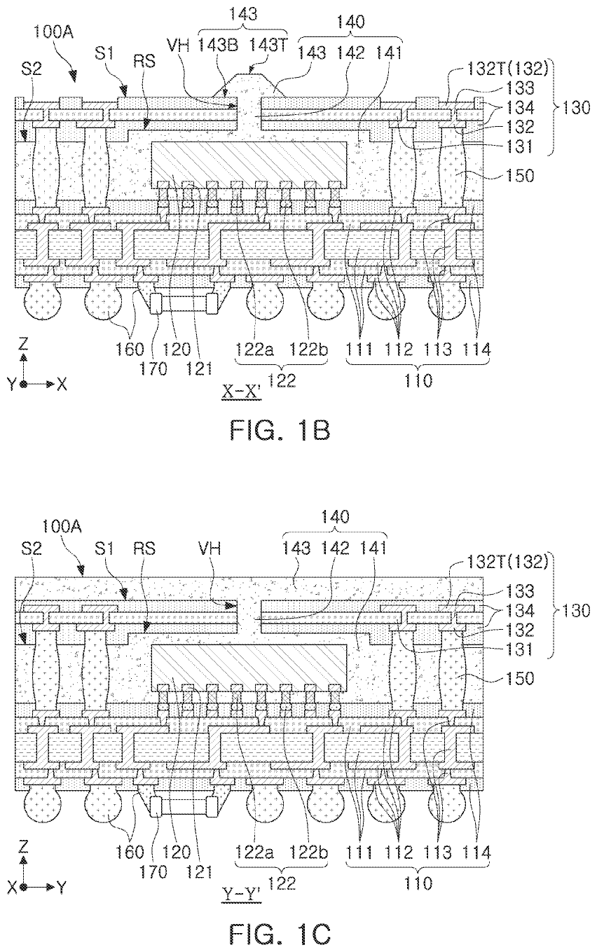

FIG. 1A is a diagram illustrating an upper surface S1 of an upper substrate 130 of a semiconductor package 100A, according to an embodiment. FIG. 1B is a cross-sectional diagram illustrating the semiconductor package 100A illustrated in FIG. 1A taken along line X-X′. FIG. 1C is a cross-sectional diagram illustrating the semiconductor package 100A illustrated in FIG. 1A taken along line Y-Y′.

Referring to FIGS. 1A, 1B, and 1C, a semiconductor package 100A in an embodiment may include a lower substrate 110, a semiconductor chip 120, an upper substrate 130, and an insulating member 140. Also, the semiconductor package 100A may further include an interconnect structure 150, connection bumps 160, and/or a passive device 170.

Referring to FIG. 1A, an upper substrate 130 may include an upper interconnection layer 132 and an upper protective layer 134. A portion of an insulating material may come out from a through-hole VH and may form a mold line 143 on the upper substrate 130. A region RR may be defined by a recessed surface RS, and may include a region MR overlapping a semiconductor chip. Interconnection pads 132T may be located around the region RR.

In an embodiment, an additional path may be provided for cleaning flux residues generated in a process of connecting the upper substrate 130 to a lower substrate 110 by including the through-hole VH in the upper substrate 130 (e.g., see FIG. 1B). In the process of filling an insulating material in a region between the upper substrate 130 and the lower substrate 110, a portion of the insulating material may come out along the through-hole VH and may form a mold line 143 on the upper substrate 130. Depending on a flow of the insulating material, quality of the filling process may be improved by discharging voids VD to the outside of the package structure. Flux residues may be reduced in an upper substrate 130 having a cavity structure with a recessed surface RS by removing flux remaining in a corner region of the cavity region. Hereinafter, each of components of the semiconductor package 100A will be described in greater detail with reference to the drawings.

The lower substrate 110 may be configured as a support substrate on which the semiconductor chip 120 is mounted, and may be a package substrate including a lower interconnection layer 112 configured to redistribute the semiconductor chip 120. The package substrate may include a printed circuit substrate (PCBs), a ceramic substrate, a glass substrate, and a tape wiring substrate. For example, the lower substrate 110 may include an insulating layer 111, a lower interconnection layer 112, a lower interconnection via 113, and a lower protective layer 114.

In various embodiments, the insulating layer 111 may include insulating resin. The insulating resin may include a thermosetting resin such as an epoxy resin, a thermoplastic resin such as a polyimide resin, a resin in which an inorganic filler and/or a glass fiber (or a glass cloth or a glass fabric) is impregnated in the thermosetting resin or the thermoplastic resin, such as prepreg, Ajinomoto build-up film (ABF), FR-4, bismaleimide triazine (BT), or photosensitive resin such as photoimageable dielectric (PID). The insulating layer 111 may include a plurality of insulating layers 111 stacked in a vertical direction (Z-axis direction), where each layer may be a different material. Depending on processes, a boundary between the plurality of insulating layers 111 may be indistinct. While three-layer insulating layers 111 are illustrated in the drawing, embodiments are not intended to be limited thereto. Among the insulating layers 111, the core insulating layer 111 disposed in the center may have a thickness greater than those of the upper and lower insulating layers 111. The core insulating layer 111 may improve rigidity of the substrate such that warpage of the substrate may be prevented. The core insulating layer 111 may be formed using, for example, a copper clad laminate (CCL), an unclad CCL, a glass substrate, or a ceramic substrate. In various embodiments, the substrate 110 may not include the core insulating layer 111. A lower protective layer 114 configured to protect the interconnection layer 112 from external physical/chemical damage may be disposed on the uppermost and/or lowermost insulating layer 111 of the plurality of insulating layers 111. The lower protective layer 114 may be a solder resist layer. The solder resist layer may include an insulating material and may be formed using, for example, prepreg, ABF, FR-4, BT, or photo solder resist (PSR).

The lower interconnection layer 112 may include, for example, copper (Cu), aluminum (Al), silver (Ag), tin (Sn), gold (Au), nickel (Ni), lead (Pb), titanium (Ti), or a metal material including alloys thereof. The lower interconnection layer 112 may include, for example, a ground pattern, a power pattern, and/or a signal pattern. The signal pattern may provide a path through which various signals, such as data signals, can be transmitted/received. The lower interconnection layer 112 may be provided as a plurality of lower interconnection layers 112 respectively disposed on the plurality of insulating layers 111, where the lower interconnection layers 112 can be electrically connected. The plurality of lower interconnection layers 112 may be electrically connected to each other through the lower interconnection vias 113, where the lower interconnection vias 113 can be interposed between the lower interconnection layers 112. The lower interconnection layer 112 may include a landing pad on which a semiconductor chip 120, an interconnect structure 150, connection bumps 160, and a passive device 170 are mounted. The landing pad may be formed to have different pitches depending on a component to be mounted. In an example, the lowermost lower interconnection layer 112 in contact with the connection bumps 160 may be formed to have a thickness greater than that of the upper lower interconnection layers 112 thereon. The number of the lower interconnection layers 112 may be determined according to the number of the insulating layers 111 and may include more or fewer layers than the example illustrated in the drawing.

The lower interconnection vias 113 may be electrically connected to the lower interconnection layers 112 and may include a signal via, a ground via, and a power via. The lower interconnection vias 113 may include, for example, copper (Cu), aluminum (Al), silver (Ag), tin (Sn), gold (Au), nickel (Ni), lead (Pb), titanium (Ti), or a metal material including alloys thereof. The lower interconnection via 113 may have a form of a filled via in which a metal material is filled in the via hole or a conformal via in which a metal material is formed along an inner wall of the via hole. The lower interconnection via 113 may be integrated with the lower interconnection layer 112, but embodiments thereof are not limited thereto.

The semiconductor chip 120 may be disposed on the lower substrate 110 and may include connection pads 121, where the connection pads 121 can provide electrical connections to the semiconductor chip 120. The bump structures 122 may be spaced apart from each other by the same distance between connection pads 121 below the semiconductor chip 120. The bump structures 122 may electrically connect the connection pads 121 of the semiconductor chip 120 to the lower interconnection layer 112. The bump structures 122 may include a first portion 122a in contact with the connection pads 121 and a second portion 122b connecting the first portion 122a to the lower interconnection layer 112. The second portion 122b may be disposed in the lower protective layer 114. For example, the first portion 122a may be configured as a metal post portion, and the second portion 122b may be configured as a solder portion including a metal having a low melting point, but an example embodiment thereof is not limited thereto. In various embodiments, the bump structures 122 may include only the second portion 122b. The metal having a low melting point may include tin (Sn), indium (In), bismuth (Bi), antimony (Sb), copper (Cu), silver (Ag), zinc (Zn), lead (Pb), or alloys thereof (e.g., Sn—Ag—Cu).

The semiconductor chip 120 may include silicon (Si), germanium (Ge), or gallium arsenide (GaAs), and various types of integrated circuits may be formed thereon. An integrated circuit may be implemented as a processor chip such as a central processor (e.g., CPU), a graphic processor (e.g., GPU), a field programmable gate array (FPGA), an application processor (AP), a digital signal processor, a cryptographic processor, a microprocessor, or a microcontroller, but embodiments are not limited thereto. The integrated circuit may be implemented as a logic chip, such as analog-to-digital converters or an application-specific IC (ASIC), a memory chip, such as a volatile memory (e.g., DRAM) or a non-volatile memory (e.g., ROM and a flash memory), etc.

The upper substrate 130 may be configured as a substrate disposed on the lower substrate 110 and the semiconductor chip 120 and may provide a redistribution layer on the semiconductor package 100A. The upper substrate 130 may be referred to as an interposer substrate disposed between a lower package and an upper package in a package-on-package structure. The upper substrate 130 may include an insulating layer 131, an upper interconnection layer 132, an upper interconnection via 133, and an upper protective layer 134. The insulating layer 131, the upper interconnection layer 132, the upper interconnection via 133, and the upper protective layer 134 may be configured the same as or similar to the insulating layer 111, the lower interconnection layer 112, the lower interconnection via 113, and the lower protective layer 114 of the lower substrate 110 described above, and overlapping descriptions thereof will not be provided.

An upper surface of the upper substrate 130 may be referred to as a first surface S1, and a lower surface of the upper substrate 130 may be referred to as a second surface S2, where the first surface S1 can be an exposed surface, and the second surface S2 can be a buried surface. The upper substrate 130 may have a recessed surface RS having a step difference from the second surface S2, where the thickness of the upper substrate 130 can be less between the first surface S1 and the recessed surface RS than between the first surface S1 and the second surface S2. The recessed surface RS may be a lower surface of the upper protective layer 134, where the recessed surface RS can be defined by the upper protective layer 134. A width of the recessed surface RS may be greater than that of the semiconductor chip 120, such that the recessed surface RS may extend beyond opposite sides of the semiconductor chip 120. The region RR defined by the recessed surface RS may include a region MR overlapping a semiconductor chip.

The upper interconnection layer 132 may include interconnection pads 132T. The interconnection pads 132T may be configured as uppermost upper interconnection layers 132 the most adjacent to the upper surface S1 of the upper substrate 130, where at least a portion of the interconnection pads 132T may be exposed on the upper surface S1. The interconnection pads 132T may be disposed to surround a region RR defined by the recessed surface RS and the region MR overlapping a semiconductor chip.

The upper substrate 130 may have at least one through-hole VH extending from the recessed surface RS to the first surface S1. The through-hole VH may extend perpendicularly (Z-axis direction) to the recessed surface RS. The through-hole VH may be disposed in the region RR defined by the recessed surface RS.

The insulating member 140 may encapsulate at least a portion of the semiconductor chip 120 on the lower substrate 110, where the insulating member 140 may fill a space between the semiconductor chip 120 and the upper substrate 130. The insulating member 140 may include a thermosetting resin such as an epoxy resin, a thermoplastic resin such as a polyimide resin, a resin in which an inorganic filler and/or a glass fiber (or a glass cloth or a glass fabric) is impregnated in the thermosetting resin or the thermoplastic resin, such as prepreg, ABF, FR-4, BT, or an epoxy molding compound (EMC). The insulating member 140 may have a molded underfill (MUF) structure integrally formed with the underfill resin between the semiconductor chip 120 and the lower substrate 110, but embodiments are not limited thereto. In various embodiments, the insulating member 140 may have a capillary underfill (CUF) structure in which an underfill resin disposed below the semiconductor chip 120 is distinct.

The insulating member 140 may include a first portion 141 covering at least a portion of each of the semiconductor chip 120 and the interconnect structure 150 between the upper substrate 130 and the lower substrate 110, and a second portion 142 extending from the first portion 141 into the through-hole VH, and a third portion 143 extending from the second portion 142 and covering at least a portion of the first surface S1 of the upper substrate 130. The interconnect structure 150 can extend through the first portion 141 of the insulating member 140 and electrically connect the lower substrate 110 to the upper substrate 130.

The first portion 141 may fill a region between the second surface S2 of the upper substrate 130 and the upper surface of the lower substrate 110, and a region between the recessed surface RS of the upper substrate 130 and the upper surface of the lower substrate 110. The first portion 141 may encapsulate at least a portion of each of the semiconductor chip 120 and the interconnect structure 150 in a region between the upper substrate 130 and the lower substrate 110. The first portion 141 may encapsulate at least a portion of the bump structures 122 electrically connected to the semiconductor chip 120 below the semiconductor chip 120, where the first portion 141 can fills spaces between bump structures 122. The first portion 141 may be referred to as an encapsulant 141.

The second portion 142 may fill a region within the through-hole VH. The second portion 142 may be a portion of the insulating member 140 on a level higher than a level of the recessed surface RS of the upper substrate 130 and a level lower than a level of the first surface S1 of the upper substrate 130. The second portion 142 may be a portion extending from the first portion 141 into the through-hole VH.

The third portion 143 may extend in one direction, for example, in the first direction (Y-axis direction) on the first surface S1 of the upper substrate 130, where the third portion 143 may extend above the first surface S1. The third portion 143 may be spaced apart from the interconnection pads 132T, where the third portion 143 can be separated from the interconnection pads 132T by the upper protective layer 134. The third portion 143 may be disposed on the region RR defined by the recessed surface RS of the upper substrate 130. The third portion 143 may be connected to the first portion 141 through a through-hole VH. In an embodiment, a cross-section of the third portion 143 (on the ZX plane) may have a trapezoidal shape of which a width of the lower end 143B may be greater than a width of the upper end 143T, but an example embodiment thereof is not limited thereto. The lower end 143B of the third portion 143 may cover at least a portion of the first surface S1 of the upper substrate 130. A width of the lower end 143B of the third portion 143 may be greater than a diameter of the through-hole VH. The third portion 143 may be referred to as a mold line 143 (e.g., see FIG. 1A).

The interconnect structure 150 may be disposed between the second surfaces S2 of the lower substrate 110 and the upper substrate 130, and may provide a vertical connection path electrically connecting the lower interconnection layer 112 to the upper interconnection layer 132. The interconnect structure 150 may have a columnar shape, a spherical shape, or a ball shape, formed of, for example, a metal having a low melting point such as tin (Sn), indium (In), bismuth (Bi), antimony (Sb), copper (Cu), silver (Ag), zinc (Zn), lead (Pb) or alloys thereof (e.g., Sn—Ag—Cu).

The connection bumps 160 may be disposed below the lower substrate 110 and may be electrically connected to the lower interconnection layer 112. The connection bumps 160 may physically and/or electrically connect the semiconductor package 100A to an external device. The connection bumps 160 may include a conductive material and may have a ball, pin, or lead shape. For example, the connection bumps 160 may be configured as solder balls. In various embodiments, at least one passive device 170 can be disposed adjacent to the connection bumps 160, where the passive device 170 may be disposed below the lower substrate 110 and electrically connected to the connection bumps 160. The passive device 170 may include, for example, a capacitor such as a multilayer ceramic capacitor (MLCC) or a low inductance chip capacitor (LICC), an inductor, a bead, or the like. In a non-limiting example, the passive device 170 may be configured as a land-side capacitor (LSC). However, embodiments are not limited thereto. In another non-limiting example, the passive device 170 may be configured as a die-side capacitor (DSC) mounted on an upper surface of the lower substrate 110 or an embedded type capacitor embedded in the lower substrate 110.

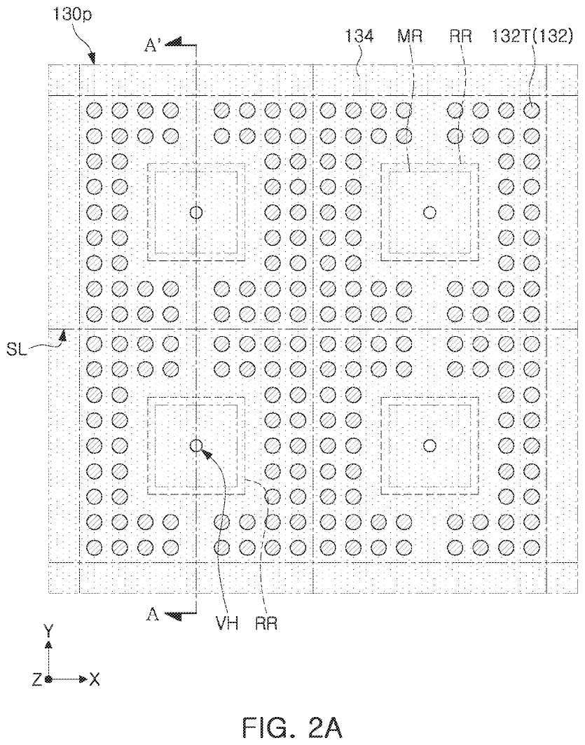

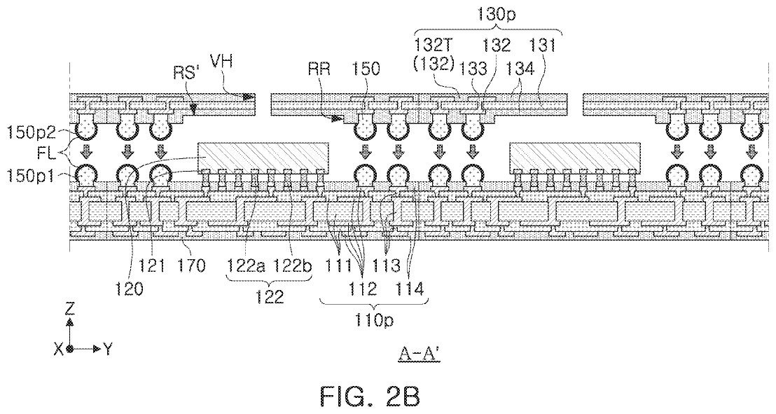

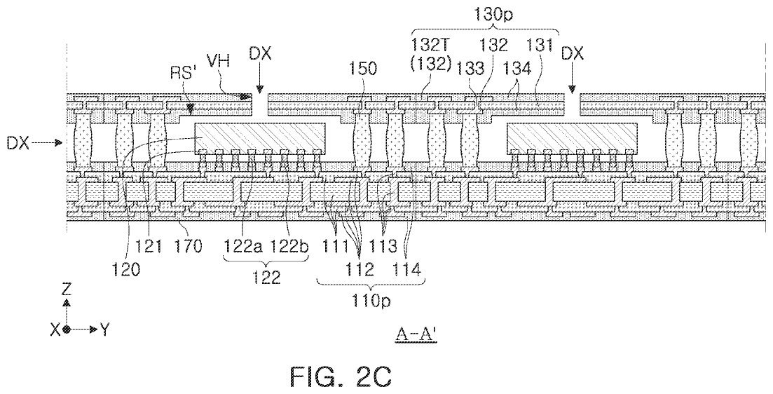

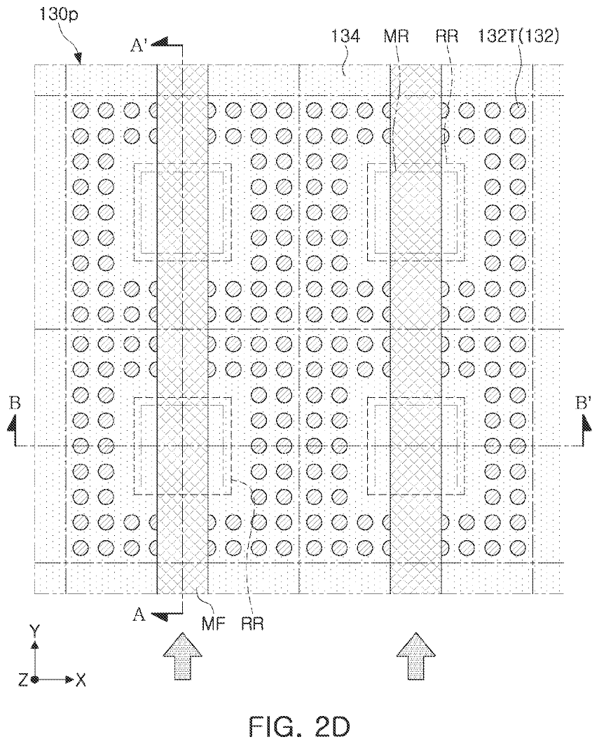

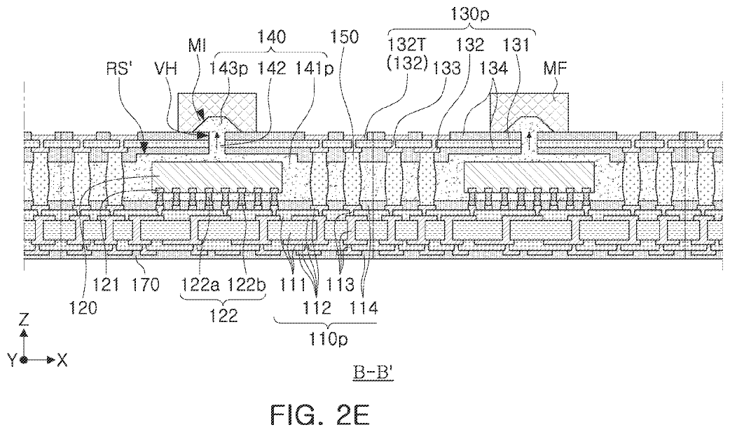

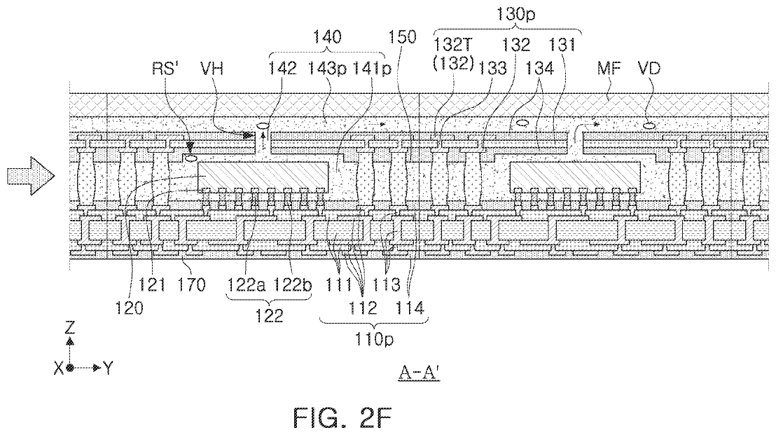

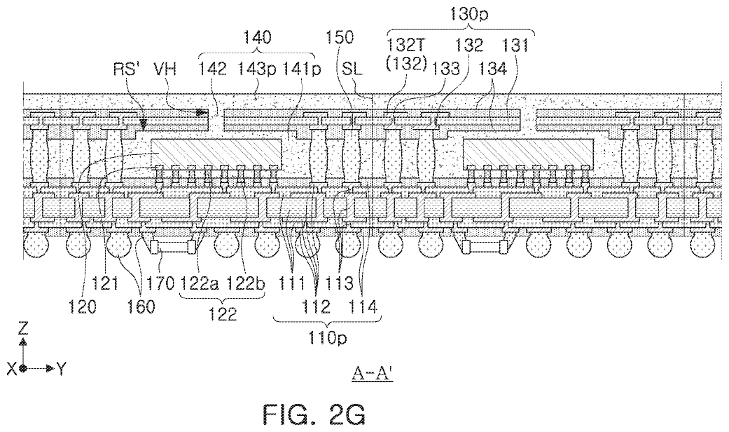

Hereinafter, a method of manufacturing the semiconductor package 100A illustrated in FIGS. 1A to 1C will be described with reference to FIGS. 2A to 2G.

FIGS. 2A to 2G are diagrams and cross-sectional diagrams illustrating processes of a method of manufacturing a semiconductor package 100A according to an embodiment.

FIG. 2A is a diagram illustrating an upper surface of a preliminary upper substrate 130p during the process of manufacturing the semiconductor package 100A, and FIG. 2B is a cross-sectional diagram illustrating the preliminary upper substrate 130p illustrated in FIG. 2A taken along line A-A′.

Referring to FIGS. 2A and 2B, a preliminary upper substrate 130p may be attached to a preliminary lower substrate 110p on which a semiconductor chip 120 is mounted. The preliminary lower substrate 110p and the preliminary upper substrate 130p may be configured as strip substrates in which units corresponding to the lower substrate 110 and the upper substrate 130 described with reference to FIGS. 1A to 1C are vertically and horizontally connected. For example, the preliminary upper substrate 130p may include a plurality of units separated by a sawing line SL.

Referring to FIG. 2B, the preliminary lower substrate 110p may include an insulating layer 111, a lower interconnection layer 112, a lower interconnection via 113, and a lower protective layer 114. The insulating layer 111 may be formed using, for example, a copper clad laminate. The lower interconnection layer 112 and the lower interconnection via 113 may be formed on both surfaces of the insulating layer 111 using a photolithography process, a plating process, or an etching process. The lower protective layer 114 may be formed by applying a solder resist ink (e.g., PSR ink).

The first preliminary interconnect structures 150p1 may be disposed on the preliminary lower substrate 110p. The first preliminary interconnect structures 150p1 may be formed by applying a solder paste including tin (Sn) or an alloy including tin (Sn). After the first preliminary interconnect structures 150p1 is formed, a flux layer FL may be formed, where the flux layer FL may be formed on the exposed surfaces of the first preliminary interconnect structures 150p1 and second preliminary interconnect structures 150p2. The flux layer FL may be formed by applying a liquid or a gel type base material to a surface of the first preliminary interconnect structures 150p1 and second preliminary interconnect structures 150p2, but is not intended to be limited thereto, and the flux layer FL may be included in the first preliminary interconnect structures 150p1. The flux layer FL may prevent oxidation of solder in a subsequent reflow process and may improve wettability and diffusibility. Flux residues can be generated in the process of connecting the upper and lower substrates to each other.

The preliminary upper substrate 130p may include an insulating layer 131, an upper interconnection layer 132, an upper interconnection via 133, an upper protective layer 134, and a second preliminary interconnect structures 150p2. The insulating layer 131, the upper interconnection layer 132, the upper interconnection via 133, the upper protective layer 134, and the second preliminary interconnect structures 150p2 may be configured the same as or similar to the insulating layer 111, the lower interconnection layer 112, the lower interconnection via 113, the lower protective layer 114 and the first preliminary interconnect structures 150p1 of the preliminary lower substrate 110p described above.

In the preliminary upper substrate 130p, a through-hole VH may be formed in the region RR defined by the recessed surfaces RS′. The through-hole VH may be formed by a physical/chemical method, and the formation method is not limited to a specific process. For example, the through-hole VH may be formed by a process of drilling the preliminary upper substrate 130p using a laser drill. The preliminary upper substrate 130p may be aligned on the preliminary lower substrate 110p, such that the second preliminary interconnect structures 150p2 may be linearly aligned with and overlap the first preliminary interconnect structures 150p1 of the preliminary lower substrate 110p in a vertical direction (Z-axis direction). The preliminary lower substrate 110p and the preliminary upper substrate 130p may be aligned, such that the semiconductor chip 120 may be disposed below the recessed surfaces RS' of the preliminary upper substrate 130p.

FIG. 2C is a cross-sectional diagram illustrating a region corresponding to the [A-A′] cross-sectional surface in FIG. 2A during the process of manufacturing the semiconductor package 100A.

Referring to FIG. 2C, a cleaning process of forming an interconnect structure 150 and removing flux residues may be performed. The interconnect structure 150 may be formed using a reflow process. After the reflow process, flux residues may be removed by introducing (e.g., injecting) flux cleaning liquid DX (e.g., purified water) between the preliminary lower substrate 110p and the preliminary upper substrate 130p and through the through-hole VH, where the through-hole VH can be in fluid communication with the interior space between the preliminary upper substrate 130p and the preliminary lower substrate 110p. In an embodiment, by securing an additional flow path of the flux cleaning liquid DX through the through-hole VH formed on the preliminary upper substrate 130p, even flux remaining in a corner portion of the recessed surfaces RS' of the preliminary upper substrate 130p, according to the step difference between the recessed surfaces RS' of the preliminary upper substrate 130p and the lower surface of the preliminary upper substrate 130p, may be effectively removed. The lower surface of the preliminary upper substrate 130p may be configured as a portion corresponding to the lower surface of the upper substrate 130. When the through-hole VH is not formed in the preliminary upper substrate 130p, a cleaning rate of the corner portion may decrease due to the step difference between the recessed surfaces RS' and the lower surface of the preliminary upper substrate 130p, and the flux residues remaining in the location may degrade quality of an encapsulant to be filled later.

FIG. 2D is a diagram illustrating an upper surface of the preliminary upper substrate 130p during the process of manufacturing the semiconductor package 100A, FIG. 2E is a cross-sectional diagram illustrating the preliminary upper substrate 130p illustrated in FIG. 2D, and FIG. 2F is a cross-sectional diagram illustrating the preliminary upper substrate 130p illustrated in FIG. 2D taken along line A-A′.

Referring to FIGS. 2D, 2E, and 2F, a mold frame MF may be disposed on the preliminary upper substrate 130p, and an insulating material may be filled in a region between the preliminary lower substrate 110p and the preliminary upper substrate 130p, thereby forming an encapsulating layer 141p and a preliminary mold line 143p (e.g., see FIG. 2E).

The mold frame MF may extend in a direction in which an insulating material is filled, for example, in a first direction (Y-axis direction) on the preliminary upper substrate 130p. The mold frame MF may have an inner groove MI. The inner groove MI may extend in the same direction as the direction in which the mold frame MF extends, that is, in the first direction (Y-axis direction). A width of a lower end of the cross-section of the inner groove MI (on the ZX plane) may be larger than a diameter of the through-hole VH (e.g., see FIG. 2E).

The insulating material may include liquid or gel-type insulating resin (e.g., EMC). In the example embodiment, as described above, by effectively removing flux residues, fillability of an insulating material may improve. The insulating material may be transferred in the same direction as the direction in which the mold frame extends, that is, in the first direction (Y-axis direction). The void VD formed in the process of filling the insulating material may be discharged onto the preliminary upper substrate 130p through the through-hole VH. The void VD may be transferred in the same direction as the direction in which the insulating material is transferred, that is, in the first direction.

The insulating material may form an encapsulating layer 141p encapsulating at least a portion of each of the semiconductor chip 120 and the interconnect structures 150 in a region between the preliminary lower substrate 110p and the preliminary upper substrate 130p. The insulating material may fill a region within the through-hole VH and may fill the inner groove MI of the mold frame MF on a level higher than a level of the upper surface of the preliminary upper substrate 130p.

The insulating material may form a preliminary mold line 143p connected to the encapsulating layer 141p through a through-hole VH. The shape of the preliminary mold line 143p may be determined by the inner groove MI of the mold frame MF. The shape of the cross-section (on the ZX plane) of the preliminary mold line 143p may be a trapezoid of which a width of a lower end may be greater than a width of an upper end, but is not limited thereto. The preliminary mold line 143p may extend in the same direction as a transfer direction of the insulating material, that is, in the first direction. The encapsulating layer 141p and the preliminary mold line 143p may be formed by curing the previously filled insulating material.

The preliminary upper substrate 130p may have at least one through-hole VH per unit. At least one preliminary mold line 143p may be formed on a plurality of units aligned in the first direction (Y-axis direction). Referring to FIGS. 2D and 2E, a preliminary mold line 143p extending in the first direction (Y-axis direction) may be spaced apart from another preliminary mold line 143p in parallel in the second direction.

FIG. 2G is a cross-sectional diagram illustrating a region corresponding to the cross-sectional surface [A-A′] in FIG. 2A during the process of manufacturing the semiconductor package 100A.

Referring to FIG. 2G, a semiconductor package (“100A” in FIGS. 1A to IC) may be formed by mounting connection bumps 160 and/or a passive device 170 on a lower surface of the preliminary lower substrate 110p, and cutting a strip substrate into one unit. The connection bump 160 and/or the passive device 170 may be mounted on the lower surface of the preliminary lower substrate 110p by a flip-chip method. The strip substrate may be cut-out with reference to the sawing line SL. The preliminary upper substrate 130p, the preliminary lower substrate 110p, and the encapsulating layer 141p may be cut into a size of one unit and may form the upper substrate 130, the lower substrate 110, and the encapsulant 141, respectively. The preliminary mold line 143p may be cut to have a length equal to one unit in the first direction, thereby forming the mold line 143.

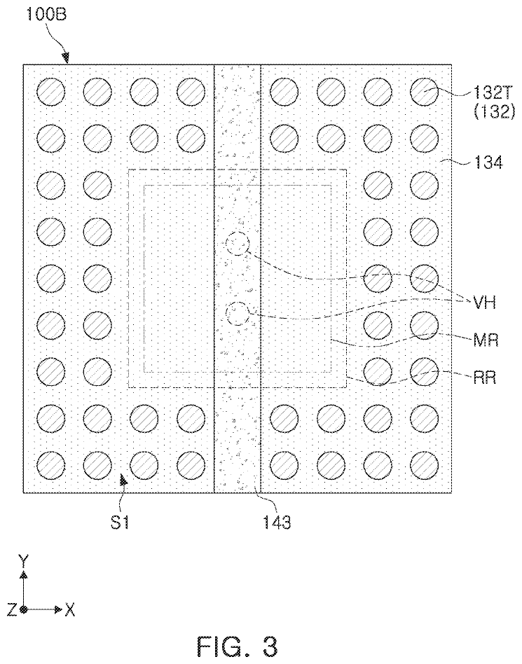

FIG. 3 is a diagram illustrating an upper surface S1 of an upper substrate 130 of a semiconductor package 100B according to an embodiment.

Referring to FIG. 3, a semiconductor package 100B in an embodiment may be configured the same as or similar to the embodiments described with reference to FIGS. 1A to 2G, other than the configuration of including a plurality of through-holes VH. The semiconductor package 100B may have two or more through-holes VH. The through-holes VH may be disposed in a region defined by the recessed surface RS of the upper substrate 130. The through-holes VH may be spaced apart from each other in the first direction (Y-axis direction). The through-holes VHs may be arranged in a row in the first direction (Y-axis direction). By including a plurality of through-holes VH as described above, the flux cleaning effect and the void discharge effect may improve by providing multiple points of ingress and egress for a flux cleaning fluid. Also, since the plurality of through-holes VH are aligned in the same first direction (Y-axis direction) as the extension direction of the mold line 143, the occupied area of the mold line may be reduced and the dispositional region of the interconnection pads may be secured.

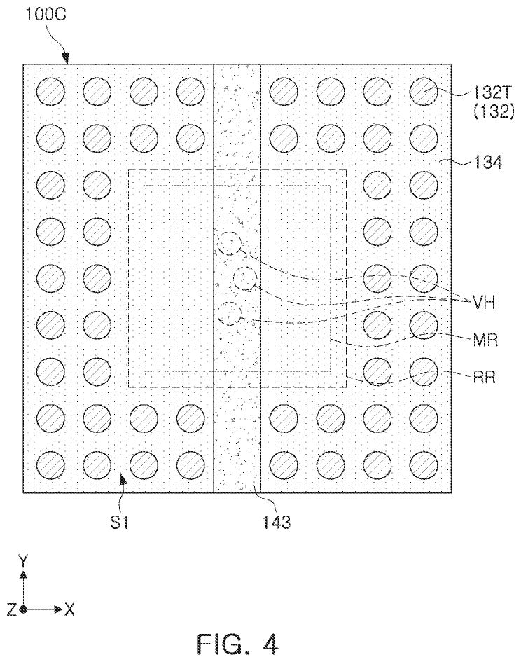

FIG. 4 is a diagram illustrating an upper surface S1 of an upper substrate 130 of a semiconductor package 100C according to an embodiment.

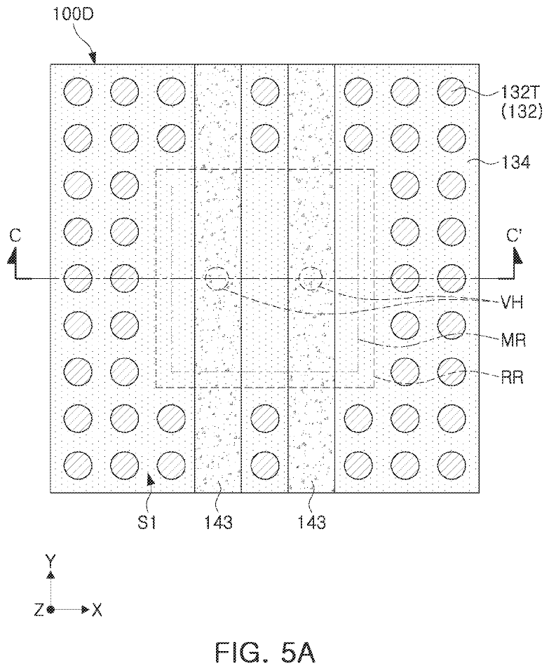

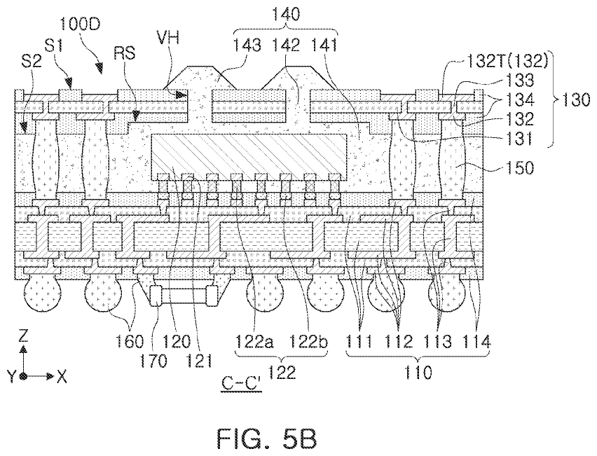

Referring to FIG. 4, a semiconductor package 100C in an embodiment may be configured the same as or similar to the embodiments described with reference to FIGS. 1A to 3, other than the configuration in which a plurality of through-holes VH may be included, and the plurality of through-holes VH may partially overlap each other in the first direction (e.g., Y direction). The semiconductor package 100C may have three or more through-holes VH, where the three or more through-holes VH can be within the inner groove MI and resulting mold line 143. The through-holes VH may be disposed in a region defined by the recessed surface RS of the upper substrate 130. The through-holes VH may be spaced apart from each other in the first direction (Y-axis direction). A portion of the through-holes VH may completely overlap each other in the first direction (Y-axis direction), and the remaining through-holes VH may partially overlap in the first direction (Y-axis direction). In various embodiments, the through-holes VH may be disposed to not overlap in the first direction (for example, the embodiment depicted in FIGS. 5A and 5B). On a plane (XY plane), the mold line 143 may have a width overlapping the entirety of the plurality of through-holes VH in a second direction (X-axis direction) perpendicular to the first direction (Y-axis direction). The width of the mold line 143 may be determined by the inner groove (“MI” in FIGS. 2D to 2F) of the mold frame (“MF” in FIGS. 2D to 2F) described with reference to FIGS. 2D to 2F.

FIG. 5A is a diagram illustrating an upper surface S1 of an upper substrate 130 of a semiconductor package 100D according to an embodiment. FIG. 5B is a cross-sectional diagram illustrating the semiconductor package 100D illustrated in FIG. 5A taken along line C-C′.

Referring to FIGS. 5A and 5B, a semiconductor package 100D in an embodiment may be configured the same as or similar to the embodiments described with reference to FIGS. 1A to 4, other than the configuration in which a plurality of through-holes VH and a plurality of mold lines 143 may be included. The semiconductor package 100D may have two or more through-holes VH. The through-holes VH may be disposed in a region defined by the recessed surface RS of the upper substrate 130. The through-holes VH may be spaced apart from each other in the second direction (X-axis direction). In an embodiment, the through-holes VH may be aligned in a line in the second direction (X-axis direction), but is not limited thereto. The two mold lines 143 may extend in the first direction from each of the through-holes VH, respectively. Each of the mold lines 143 may be spaced apart from each other in the second direction (X-axis direction) and may extend parallel to the first direction (Y-axis direction). The mold lines 143 may be spaced apart from the interconnection pads 132T. At least a portion of the interconnection pads 132T may be disposed between the plurality of mold lines 143. By including the plurality of through-holes VH, the flux cleaning effect and the void discharging effect may be improved. Also, the plurality of through-holes VH, and the plurality of mold lines 143 formed on the through-holes VH may be spaced apart from each other in the second direction (X-axis direction) intersecting the extension direction of the mold lines 143, such that an additional dispositional region of the interconnection pads 132T may be between the adjacent mold lines 143 spaced apart from each other.

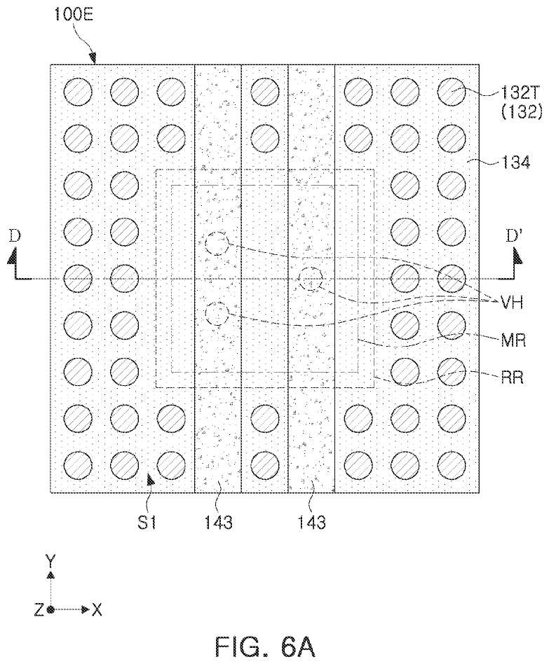

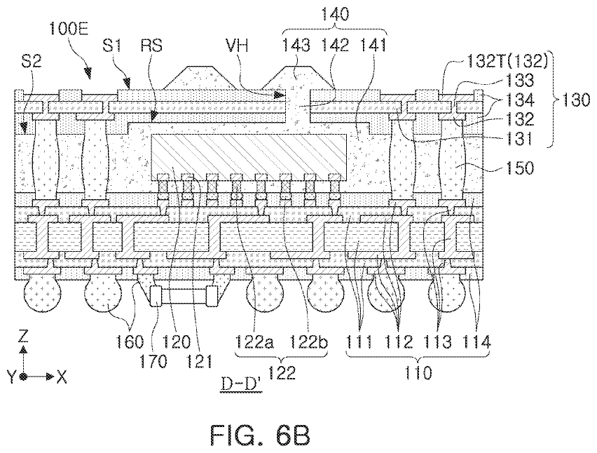

FIG. 6A is a diagram illustrating an upper surface S1 of an upper substrate 130 of a semiconductor package 100E according to an embodiment. FIG. 6B is a cross-sectional diagram illustrating the semiconductor package 100E illustrated in FIG. 6A taken along line D-D′.

Referring to FIGS. 6A and 6B, a semiconductor package 100E in an embodiment may be configured the same as or similar to the embodiments described with reference to FIGS. 1A to 5B other than the configuration in which a plurality of through-holes VH and a plurality of mold lines 143 may be included and the configuration in which a portion of the mold line 143 may be formed on the plurality of through-holes VH spaced apart from each other in the first direction. The semiconductor package 100E may have two or more through-holes VH. The through-holes VH may be disposed in a region defined by the recessed surface RS of the upper substrate 130. The through-holes VH may be spaced apart from each other in the first direction (Y-axis direction) and the second direction (X-axis direction). A portion of the two or more through-holes VH may be aligned in the first direction (Y-axis direction), where one or more through-holes VH may be aligned with a first mold line 143 and one or more through-holes VH may be aligned with a second mold line 143. The mold lines 143 may extend in the first direction from the through-holes VH, respectively. The mold lines 143 may be spaced apart from each other in the second direction (X-axis direction) and may extend parallel to the first direction (Y-axis direction). The mold lines 143 may be spaced apart from the interconnection pads 132T. At least a portion of the interconnection pads 132T may be disposed between the plurality of mold lines 143.

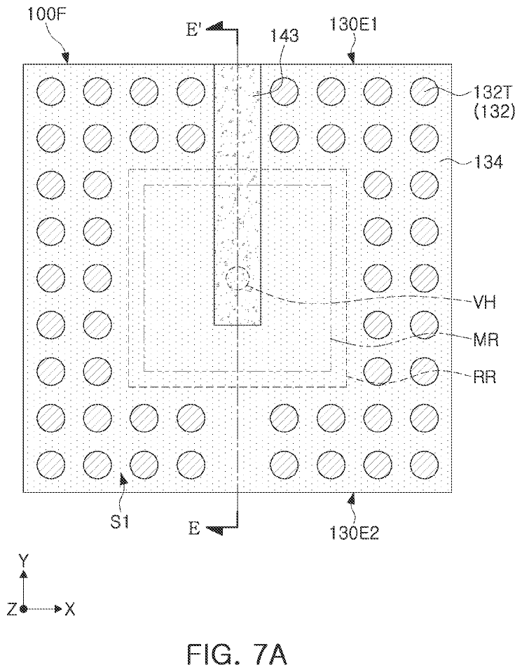

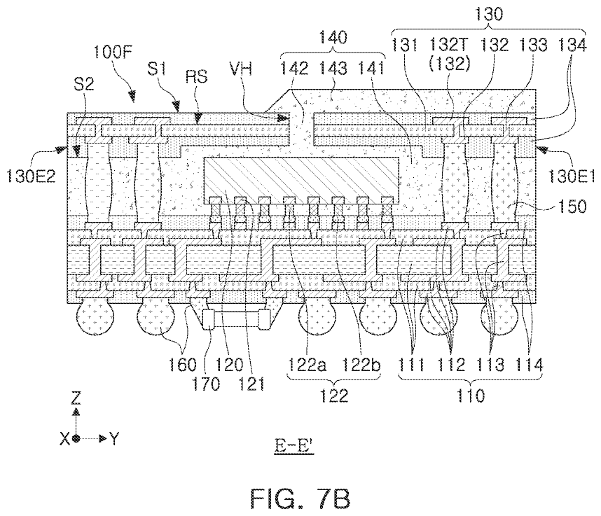

FIG. 7A is a diagram illustrating an upper surface of an upper substrate of a semiconductor package according to an embodiment. FIG. 7B is a cross-sectional diagram illustrating the semiconductor package illustrated in FIG. 7A taken along line E-E′.

Referring to FIGS. 7A and 7B, a semiconductor package 100F in an embodiment may be configured the same as or similar to the embodiments described with reference to FIGS. 1A to 6B, other than the configuration in which the mold line 143 may extend only to one side of upper substrate 130. The mold line 143 may have a shape extending to the one side 130E1 of the upper substrate 130. As described with reference to FIGS. 2D to 2F, the insulating material may be transferred in the first direction (Y-axis direction) through the through-hole VH. At least a portion of the insulating material may be transferred to the other side 130E2 of the upper substrate 130 disposed opposite to the one side end 130E1 in the first direction in which the mold line 143 extends on the upper substrate 130. The mold line 143 may be formed by curing the insulating material, and may have a different shape depending on the extent to which the insulating material is transferred. One cross-sectional surface (on the YZ plane) of the mold line 143 may appear in the form of a slope on one side. Referring to FIGS. 2D to 2F, an embodiment in FIGS. 7A and 7B may be a semiconductor package of units most adjacent to a region in which the filling of insulating material may start.

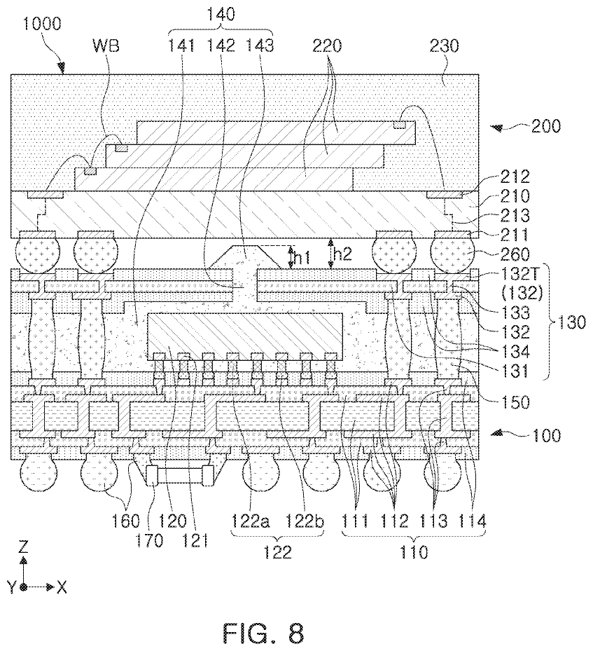

FIG. 8 is a cross-sectional diagram illustrating a semiconductor package 1000 according to an embodiment.

Referring to FIG. 8, a semiconductor package 1000 in an embodiment may include a lower package 100 and an upper package 200. The lower package 100 may be illustrated the same as the semiconductor package 100A illustrated in FIG. 1A, or may be replaced with semiconductor packages 100B, 100C, 100D, 100E, and 100F or semiconductor packages configured similarly to the embodiments described with reference to FIGS. 3 to 7B.

The upper package 200 may include a redistribution substrate 210, one or more second semiconductor chips 220, and a second encapsulant 230, where the second encapsulant 230 can surround the one or more second semiconductor chip 220. The redistribution substrate 210 may include a lower pad 211 and an upper pad 212 electrically connected to an external entity on a lower surface and an upper surface, respectively. Also, the redistribution substrate 210 may include a redistribution circuit 213 electrically connecting the lower pad 211 to the upper pad 212.

The one or more second semiconductor chips 220 may be mounted on the redistribution substrate 210 by wire bonding or flip chip bonding. A plurality of second semiconductor chips 220 may be vertically stacked on the redistribution substrate 210 and may be electrically connected to the upper pad 212 of the redistribution substrate 210 by a bonding wire WB. In an example, the one or more second semiconductor chips 220 may include a memory chip, and the first semiconductor chip 120 may include an application processor (AP) chip.

The second encapsulant 230 may include a material the same as or similar to that of the encapsulant 140 of the lower package 100. The upper package 200 may be physically and electrically connected to the lower package 100 by the upper connection bumps 260. The upper connection bumps 260 may be electrically connected to the redistribution circuit 213 in the redistribution substrate 210 through the lower pad 211 of the redistribution substrate 210. The upper connection bump 260 may include a metal having a low melting point, for example, tin (Sn) or an alloy including tin (Sn).

A height, h1, of the third portion 143 of the lower package 100 or the mold line 143 may be lower than a height, h2, of the upper connection bump 260. The height h1 of the third portion 143 may be adjusted using the inner groove (“MI” in FIGS. 2D to 2F) of the mold frame (“MF” in FIGS. 2D to 2F).

According to the aforementioned embodiments, by including an upper substrate with a through-hole, flux residues generated in the process of connecting the upper and lower substrates to each other may be efficiently removed through the through-hole, and voids may be discharged along with a portion of the encapsulant coming out through the through-hole in the process of filling the encapsulant, such that voids in the package structure may be reduced.

While the example embodiments have been illustrated and described above, it will be apparent to those skilled in the art that modifications and variations may be made without departing from the scope in the embodiments as defined by the appended claims.

What is claimed is:

1. A semiconductor package, comprising:
a lower substrate including a lower interconnection layer;
an upper substrate on the lower substrate, including
a first surface and a second surface opposite to each other;
a recessed surface having a step difference from the second surface;
a through-hole extending from the recessed surface to the first surface and
an upper interconnection layer electrically connected to the lower interconnection layer;
a semiconductor chip disposed between the recessed surface of the upper substrate and the lower substrate, and including connection pads electrically connected to the lower interconnection layer;
an interconnect structure disposed between the second surface of the upper substrate and the lower substrate, and electrically connecting the lower interconnection layer to the upper interconnection layer; and
an insulating member including a first portion covering at least a portion of each of the semiconductor chip and the interconnect structure between the upper substrate and the lower substrate, a second portion extending from the first portion into the through-hole, and a third portion extending from the second portion and covering at least a portion of the first surface of the upper substrate.

2. The semiconductor package of claim 1, wherein
bump structures electrically connected to the connection pads of the semiconductor chip,
wherein the first portion configured to encapsulate at least a portion of the bump structures.

3. The semiconductor package of claim 2, wherein the bump structures are spaced apart from each other with an equal distance therebetween.

4. The semiconductor package of claim 1, wherein a width of a lower end of the third portion in contact with the first surface of the upper substrate is greater than a diameter of the through-hole.

5. The semiconductor package of claim 1, wherein the through-hole extends perpendicular to the recessed surface.

6. The semiconductor package of claim 1, wherein a width of the recessed surface is greater than a width of the semiconductor chip.

7. The semiconductor package of claim 1, further comprising:
an upper package disposed on the upper substrate; and
upper connection bumps electrically connecting the upper package to the upper interconnection layer,
wherein a height of the third portion is lower than a height of the upper connection bumps.

8. A semiconductor package, comprising:
a lower substrate including a lower interconnection layer;
a semiconductor chip disposed on the lower substrate and electrically connected to the lower interconnection layer;
an upper substrate disposed on the semiconductor chip and including interconnection pads surrounding a region overlapping the semiconductor chip, and at least one through-hole spaced apart from the interconnection pads;
at least one mold line disposed on the upper substrate and spaced apart from the interconnection pads and extending in a first direction from the through-hole;
an encapsulant configured to encapsulate at least a portion of the semiconductor chip between the upper substrate and the lower substrate and connected to the mold line through the through-hole.

9. The semiconductor package of claim 8, wherein the at least one through-hole includes a plurality of through-holes spaced apart from each other in the first direction.

10. The semiconductor package of claim 9, wherein the plurality of through-holes are aligned in a row in the first direction.

11. The semiconductor package of claim 10, wherein at least some of through-holes among the plurality of through-holes partially overlap in the first direction.

12. The semiconductor package of claim 8, wherein the at least one through-hole includes a plurality of through-holes spaced apart from each other in a second direction intersecting the first direction.

13. The semiconductor package of claim 12, wherein the at least one mold line includes a plurality of mold lines spaced apart from each other and extending in the first direction from the plurality of through-holes.

14. The semiconductor package of claim 13, wherein at least some of the interconnection pads are disposed between an adjacent pair of the plurality of mold lines.

15. The semiconductor package of claim 8, wherein the at least one mold line extends to at least one side end of the upper substrate in a first direction.

16. A method of manufacturing a semiconductor package, the method comprising:
disposing a semiconductor chip on a preliminary lower substrate;
preparing a preliminary upper substrate having a recessed surface and a through-hole extending from the recessed surface, wherein the recessed surface has a step difference from a lower surface of the preliminary upper substrate;
forming interconnect structures between the preliminary lower substrate and the preliminary upper substrate;
introducing a flux cleaning liquid between the preliminary lower substrate and the preliminary upper substrate and through the through-hole; and
forming an encapsulating layer encapsulating at least a portion of each of the semiconductor chip and the interconnect structures and a preliminary mold line connected to the encapsulating layer through the through-hole by filling an insulating material between the preliminary lower substrate and the preliminary upper substrate that extends through the through-hole.

17. The method of claim 16, further comprising:
disposing a mold frame on the preliminary upper substrate after spraying the flux cleaning liquid,
wherein the mold frame has an inner groove extending in the first direction.

18. The method of claim 16,
wherein the insulating material is transferred in the first direction, and
wherein the preliminary mold line extends in the first direction.

19. The method of claim 18, wherein the void formed in the process of filling the insulating material is discharged to the preliminary upper substrate through the through-hole.

20. The method of claim 16, further comprising:
cutting each of the preliminary lower substrate, the encapsulating layer, the preliminary mold line, and the preliminary upper substrate into one unit after the forming the preliminary mold line.
